(19) United States
(12) Patent Application Publication
(10) Pub. No.: US 2013/0087827 A1
(43) Pub. Date: Apr. 11, 2013

(54) ORGANIC LIGHT-EMITTING DIODE AND METHOD OF MAKING SAME

(71) Applicant: LI-YING WANG HE, Tu-Cheng (TW)

(72) Inventor: LI-YING WANG HE, Tu-Cheng (TW)

(73) Assignee: HON HAI PRECISION INDUSTRY CO., LTD., Tu-Cheng (TW)

(21) Appl. No.: 13/315,292

(22) Filed: Dec. 9, 2011

(30) Foreign Application Priority Data
Oct. 11, 2011 (TW) 100136617

(51) Int. Cl. H01L 51/52; H01L 51/56

(52) U.S. Cl. 257/100; 438/26; 257/40; 257/E51.018

(57) ABSTRACT

An organic light-emitting diode includes a substrate layer, a cathode layer spread on the substrate layer, an organic film spread on the cathode layer and an anode layer spread on the organic film. The substrate layer is made of electrically insulative and transparent material. The cathode layer is made of transparent and electrically conductive material. The organic film includes an organic luminescent layer. Molecules of the organic film orient toward a uniform direction and the organic film radiates polarization light.

### BACKGROUND

1. Technical Field

The present disclosure generally relates to semiconductors, and particularly to an organic light-emitting diode (OLED) and a method of making same.

2. Description of Related Art

Light emitting-diode (LED) devices, also referred to as electroluminescent devices, have numerous well known advantages over other light-emitting devices currently in the market place. Among the potential advantages is brightness of light emission, reduced device volume, and reduced electrical power consumption compared to, for example, fluorescent tube. Therefore, the LED is widely used as a backlight of the liquid crystal display (LCD).

During operation of the LCD, light of the LED is polarized by a polarizer. However, the polarizer absorbs part of the light when the light passes the polarizer, which causes a low transmittance, even less than 45%, to the LCD, and finally decreases a brightness of the LCD.

What is needed, therefore, is an OLED and a method of making same which can overcome the limitations described.

### BRIEF DESCRIPTION OF THE DRAWINGS

FIG. 1 is a schematic cross-sectional view of an organic light-emitting diode in accordance with an embodiment of the present disclosure.

FIG. 2 is a schematic view of a photo-alignment process for making the organic light-emitting diode of FIG. 1.

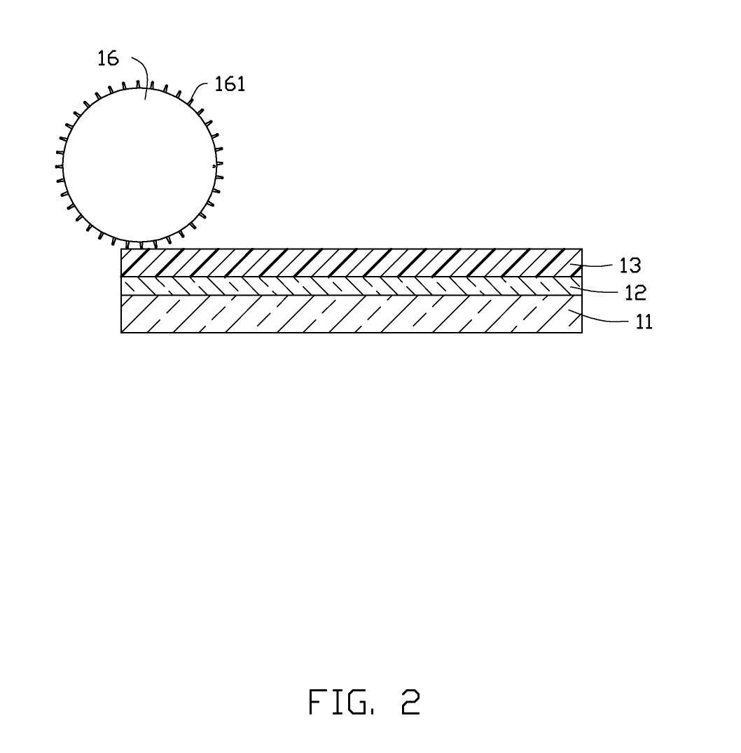

FIG. 3 is an isometric view of a roller for the photo-alignment process of FIG. 2.

FIG. 4 is a schematic cross-sectional view of an organic light-emitting diode in accordance with a second embodiment of the present disclosure.

### DETAILED DESCRIPTION

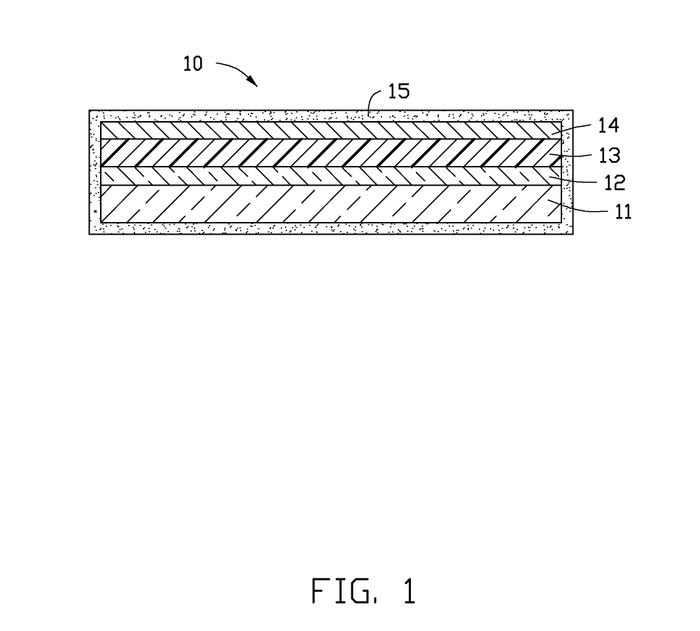

Referring to FIG. 1, an organic light-emitting diode (OLED) 10 in accordance with an embodiment of the present disclosure is shown. The OLED 10 includes a substrate layer 11, a cathode layer 12 spread on the substrate layer 11, an organic film 13 spread on the cathode layer 12 and an anode layer 14 spread on the organic film 13. A method for making the OLED 10 will be presented in detail hereinbelow.

The substrate layer 11 is plane and made of electrically insulative and transparent material, such as epoxy resin, glass epoxide, bismaleimide triazine resin, or ceramic, et al.

The cathode layer 12 is formed on the substrate layer 11 through sputtering process, vapor plating process or heat deposition process. Light of the OLED 10 transmits along a direction from the cathode layer 12 to the substrate layer 11. The cathode layer 12 is made of transparent and electrically conductive material, such as indium tin oxide (ITO), indium zinc oxide (IZO), zinc oxide (ZnO), or indium oxide (In₂O₃), et al. The cathode layer 12 provides holes to the OLED 10 but hardly hinders transmission of the light. When the cathode layer 12 is formed through the heat deposition process, a thickness of the cathode layer 12 can be controlled according to a deposition speed and a deposition time.

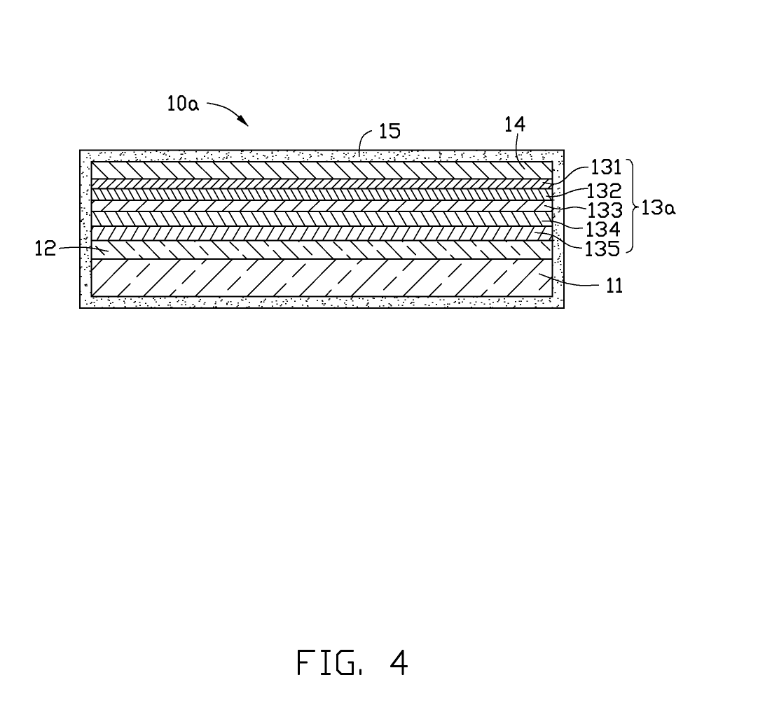

The organic film 13 is formed on the cathode layer 12 through vacuum vapor plating process. The organic film 13 is an organic luminescent layer. Referring to FIG. 4, in a second embodiment of the OLED 10a of the present disclosure, referring to FIG. 4, the organic film 13a can further include an electron injecting layer 131, an electron transmission layer 132, an organic luminescent layer 133, a hole transmission layer 134 and a hole injecting layer 135. The hole injecting layer 135, the hole transmission layer 134, the organic luminescent layer 133, the electron transmission layer 132 and the electron injecting layer 131 are formed in order from the cathode layer 12.

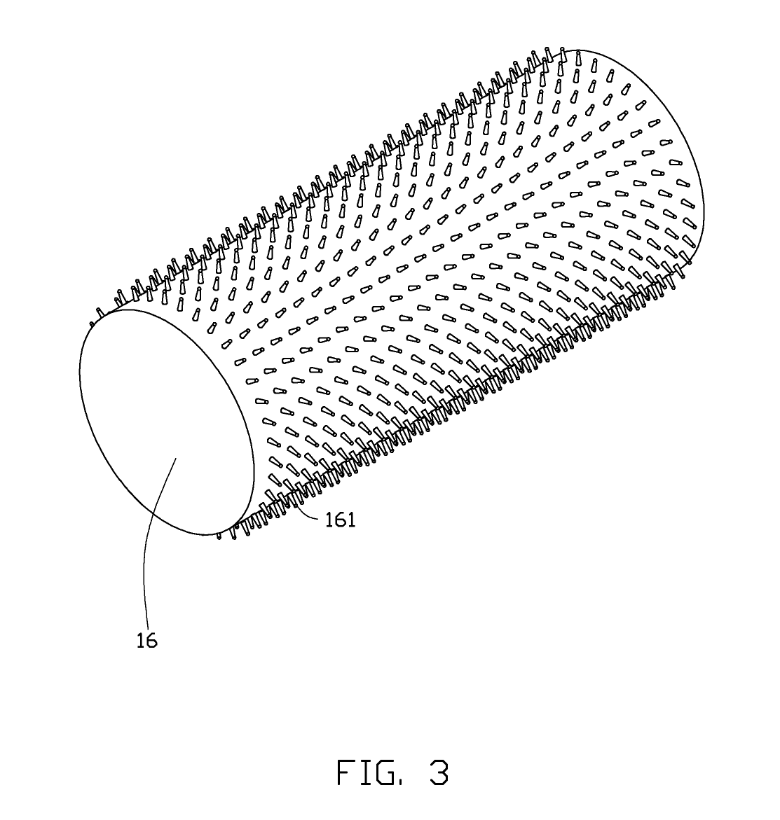

Then a photo-alignment process is carried out on the organic film 13 by a roller 16. Referring to FIG. 3, the roller 16 is generally columned A plurality of pins 161 are formed on a circumference of the roller 16. The pins 161 have identical lengths and are arranged in a matrix manner on the circumference of the roller 16. Each of pins 161 extends outwardly from the circumference of the roller 16 along a radial direction of the roller 16. Distances between tips of the pins 161 and an axis of the roller 16 are identical to each other. The tip of each of the pins 161 is smooth and spherical. The pins 161 are made of silicon or silicon dioxide. The pins 161 are integrally formed on the roller 16.

During the photo-alignment process, the roller 16 rolls on the organic film 13 from one side to an opposite side. The pins 161 contact the organic film 13 in turn. Molecular bonds between molecules of the organic film 13 are disrupted due to van der waals force between the pins 161 and the molecules of the organic film 13. The molecules of the organic film 13 are aligned along a rolling direction of the roller 16 to make the molecules of the organic film 13 orient toward a uniform direction, thus achieving a photo-alignment of the molecules of the organic film 13. After the alignment process, the molecules of the organic film 13 maintain orienting toward a uniform direction. Light radiating from the organic film 13 thus has a uniform vibration direction, which enables the OLED 10 to radiate polarization light. In this embodiment, the pins 161 extend along radial directions of the roller 16. But in other embodiment, the pins 161 can extend along tangential directions of the roller 16 or other directions as long as distances between tips of the pins 161 and the axis of the roller 16 are identical to each other.

In a subsequent step, the anode layer 14 is formed on the organic film 13.

The anode layer 14 is made of aluminum, argentums, aurum or magnesium. The anode layer 14 provides electrons to the organic film 13. The anode layer 14 also acts as a moisture-proof layer and an airproof layer for the organic film 13.

In the end, a protective jacket 15 is formed around the OLED 10 to enclose therein the substrate layer 11, the cathode layer 12, the organic film 13 and the anode layer 14.

In the OLED 10 of the present disclosure, the molecules of the organic film 13 are aligned to orient toward the uniform direction through the roller 16 with a plurality of pins 16 formed thereon. Therefore, the OLED 10 can radiate polarization light without using of polarizer. When the OLED 10 is used as a backlight of a liquid crystal display, the liquid crystal display can have a relatively high brightness.

It is to be understood, however, that even though numerous characteristics and advantages of the exemplary embodiments have been set forth in the foregoing description, together with details of the structures and functions of the embodiments, the disclosure is illustrative only; and that changes may be made in detail, especially in matters of shape, size, and arrangement of parts within the principles of the embodiments to the full extent indicated by the broad general meaning of the terms in which the appended claims are expressed.

What is claimed is:

1. An organic light-emitting diode comprising:
a substrate layer made of electrically insulative and transparent material;
a cathode layer spread on the substrate layer, the cathode being layer made of transparent and electrically conductive material;
an organic film spread on the cathode layer for radiating polarization light, the organic film comprising an organic luminescent layer, molecules of the organic film orienting toward a uniform direction ; and
an anode layer spread on the organic film.

2. The organic light-emitting diode of claim 1, wherein the organic film further comprises a hole injecting layer, a hole transmission layer, an organic luminescent layer, an electron transmission layer and an electron injecting layer, and the hole injecting layer, the hole transmission layer, the organic luminescent layer, the electron transmission layer and the electron injecting layer are formed in order from the cathode layer.

3. The organic light-emitting diode of claim 1, wherein the substrate layer is plane and made of a material selected from the group consisting of epoxy resin, glass epoxide, bismaleimide triazine resin and ceramic.

4. The organic light-emitting diode of claim 1, wherein the cathode layer is made of a material selected from the group consisting of indium tin oxide (ITO), indium zinc oxide (IZO), zinc oxide (ZnO) and indium oxide (In₂O₃).

5. The organic light-emitting diode of claim 1, wherein the anode layer is made of a material selected from the group consisting of aluminum, argentums, aurum and magnesium.

6. The organic light-emitting diode of claim 1, further comprising a protective jacket enclosing therein the substrate layer, the cathode layer, the organic film and the anode layer.

7. An method of making an organic light-emitting diode comprising the steps of:
provide an electrically insulative and transparent substrate layer;
forming a transparent and electrically conductive cathode layer on the substrate layer;
forming an organic film on the cathode layer;
rolling a roller with a plurality of pins formed thereon on the organic film to align molecules of the organic film to orient toward a uniform direction;
forming an anode layer on the organic film.

8. The method of claim 7, further comprising a step of:
forming a protective jacket to enclose therein the substrate layer, the cathode layer, the organic film and the anode layer.

9. The method of claim 7, wherein when the roller rolls on the organic film, the roller is positioned on the organic film, and the pins of the roller contact the organic film in turn.

10. The method of claim 7, wherein the roller is columned, and the pins are arranged in a matrix on a circumference of the roller.

11. The method of claim 7, wherein a tip of each of the pins is smooth and spherical, and the pins are integrally formed on the roller.

12. The method of claim 7, wherein distances between tips of the pins and an axis of the roller are identical to each other.

13. The method of claim 12, wherein the pins extend along radial directions of the roller.

14. The method of claim 12, wherein the pins extend along tangential directions of the roller.

15. The method of claim 7, wherein the pins are made of silicon or silicon dioxide.

16. The method of claim 7, wherein the substrate layer is plane and made of a material selected from the group consisting of epoxy resin, glass epoxide, bismaleimide triazine resin and ceramic.

17. The method of claim 7, wherein the cathode layer is formed on the substrate layer through one of sputtering process, vapor plating process and heat deposition process.

18. The method of claim 17, wherein the cathode layer is made of a material selected from a group consisting of indium tin oxide (ITO), indium zinc oxide (IZO), zinc oxide (ZnO) and indium oxide (In₂O₃).

19. The method of claim 17, wherein the cathode layer is formed through a heat deposition process, and a thickness of the cathode layer is controlled according to a deposition speed and a deposition time.

20. The method of claim 7, wherein the organic film is formed on the cathode layer through vacuum vapor plating process.
